(19) United States
(12) Patent Application Publication
(10) Pub. No.: US 2026/0246446 A1
(43) Pub. Date: Aug. 20, 2026

(54) SURFACE ACOUSTIC WAVE DEVICE WITH SHORTING BAR IN FAST REGION

(71) Applicant: Qorvo US, Inc., Greensboro, NC (US)

(72) Inventor: Christian Huck, Munich (DE)

(21) Appl. No.: 19/161,223

(22) PCT Filed: Jan. 30, 2024
(86) PCT No.: PCT/US2024/013510

§ 371 Date: Aug. 29, 2025

Related U.S. Application Data
(60) Provisional application No. 63/487,918, filed on Mar. 2, 2023.

(51) Int. Cl. H03H 9/145; H03H 3/08; H03H 9/02; H03H 9/25

(52) U.S. Cl. CPC H03H 9/14544; H03H 3/08; H03H 9/02559; H03H 9/02637; H03H 9/02889; H03H 9/25

(57) ABSTRACT

A surface acoustic wave, SAW, device comprises a piezoelectric substrate, an interdigitated transducer, and first and second piston mode rails. The interdigitated transducer is over the piezoelectric substrate and has first and second electrodes. The first electrode has a first bus bar (50A), a first plurality of fingers (54) extending orthogonally from the first bus bar, and a first shorting bar (56) that is parallel with the first bus bar and extends across the first plurality of fingers. The second electrode has a second bus bar (50B), a second plurality of fingers (54) extending orthogonally from the second bus bar, and a second shorting bar (56) that is parallel with the second bus bar and extends across the second plurality of fingers. The second plurality of fingers are interdigitated with the first plurality of fingers. The first piston mode rail (62) and the second piston mode rail (62) extend over distal ends of the first and second plurality of fingers.

### FIELD OF THE DISCLOSURE

The present disclosure relates to acoustic wave devices, and particularly to surface acoustic wave (SAW) devices.

### BACKGROUND

Acoustic wave devices are widely used in modern electronics. At a high level, acoustic wave devices include a piezoelectric material in contact with one or more electrodes. Piezoelectric materials acquire a charge when compressed, twisted, or distorted, and similarly compress, twist, or distort when a charge is applied to them. Accordingly, when an alternating electrical signal is applied to the one or more electrodes in contact with the piezoelectric material, a corresponding mechanical signal (i.e., an oscillation or vibration) is transduced therein. Based on the characteristics of the one or more electrodes on the piezoelectric material, the properties of the piezoelectric material, and other factors such as the shape of the acoustic wave device and other structures provided on the device, the mechanical signal transduced in the piezoelectric material exhibits a frequency dependent on the alternating electrical signal. Acoustic wave devices leverage this frequency dependence to provide one or more functions.

Surface acoustic wave (SAW) devices, such as SAW resonators and SAW filters, are used in many applications such as radio frequency (RF) filters. For example, SAW filters are commonly used in receive and transmit paths of wireless RF front ends to realize filter applications, e.g. in duplexers or multiplexers. The widespread use of SAW filters is due to, at least in part, the fact that SAW filters exhibit low insertion loss with good rejection, can achieve broad bandwidths, and are a small fraction of the size of traditional cavity and ceramic filters. As the use of SAW filters in modern RF communication systems continues, there is a need for SAW filters with sharp transitions between desired passband frequencies and frequencies that are outside of desired passbands as well as the need to reduce the size of the SAW devices while maintaining and/or improving their performance.

### SUMMARY

A surface acoustic wave (SAW) device comprises a piezoelectric substrate, an interdigitated transducer, and first and second piston mode rails. The interdigitated transducer is over the piezoelectric substrate and has first and second electrodes. The first electrode has a first bus bar, a first plurality of fingers extending orthogonally from the first bus bar, and a first shorting bar that is parallel with the first bus bar and extends across the first plurality of fingers. The second electrode has a second bus bar, a second plurality of fingers extending orthogonally from the second bus bar, and a second shorting bar that is parallel with the second bus bar and extends across the second Plurality of fingers. The second plurality of fingers are interdigitated with the first plurality of fingers. The first piston mode rail is isolated from and extends over distal ends of the first plurality of fingers. The second piston mode rail is isolated from and extends over distal ends of the second plurality of fingers.

In one embodiment, slow regions with relatively slower acoustic wave velocities are beneath the first piston mode rail and the second piston mode rail. Fast regions with relatively faster acoustic wave velocities are provided outside of the slow regions. A main region is provided between the slow regions such that the main region has acoustic wave velocities between those of the slow regions and the fast regions. The first shorting bar and the second shorting bar are over respective ones of the fast regions. The first piston mode rail and the second piston mode rail are over respective ones of the slow regions. The first piston mode rail may be parallel with the second piston mode rail, the first bus bar, the second bus bar, and the second piston mode rail.

In one embodiment, first openings are each defined in the first electrode by corresponding portions of the first bus bar, adjacent ones of the first plurality of fingers, and the first shorting bar. Similarly, second openings are each defined in the second electrode by corresponding portions of the second bus bar, adjacent ones of the second plurality of fingers, and the second shorting bar.

In one embodiment, an overcoat layer is provided over the first electrode, the second electrode, and portions of the top surface of the piezoelectric substrate, wherein the first piston mode rail and the second piston mode rail reside in the overcoat layer.

In certain embodiments, the piezoelectric substrate is formed from lithium niobate or lithium tantalate.

In one embodiment, the first electrode and the second electrode are formed from an electrode stack that has a first adhesion layer over the piezoelectric substrate; a conducting layer over the first adhesion layer; and a second adhesion layer over the conducting layer.

In one embodiment, a method for fabricating a surface acoustic wave (SAW) device, is provided. The method may include:
providing a piezoelectric substrate;
providing an interdigitated transducer over the piezoelectric substrate and comprising:
a first electrode comprising a first bus bar, a first plurality of fingers extending orthogonally from the first bus bar, and a first shorting bar that is parallel with the first bus bar and extends across the first plurality of fingers;
a second electrode comprising a second bus bar, a second plurality of fingers extending orthogonally from the second bus bar, and a second shorting bar that is parallel with the second bus bar and extends across the second plurality of fingers, wherein the second plurality of fingers are interdigitated with the first plurality of fingers;
providing a first piston mode rail that is isolated from and extends over distal ends of the first plurality of fingers; and
providing a second piston mode rail that is isolated from and extends over distal ends of the second plurality of fingers.

The SAW devices may be employed in various types of communications equipment and electronics, such as a mobile terminal.

In another aspect, any of the foregoing aspects, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is an isometric view of a representative surface acoustic wave (SAW) device of the related art.

FIG. 2 is a top view of the SAW device of FIG. 1 without piston mode rails.

FIG. 3 is a cross-sectional view in the slow region of the SAW device of FIG. 1.

FIG. 4 is a top view of a SAW device of FIG. 1 wherein piston mode rails are shown.

FIG. 5 is an isometric view of a representative surface acoustic wave (SAW) device according to one embodiment without piston mode rails.

FIG. 6 is a top view of the SAW device of FIG. 5 without piston mode rails.

FIG. 7 is a cross-sectional view of the SAW device of FIG. 5.

FIG. 8 is a top view of the SAW device of FIG. 5 wherein piston mode rails are shown in combination with shorting bars.

FIG. 9 is a plot comparing various parameters of a SAW device without piston mode rails and shorting bars and a SAW device with piston mode rails and shorting bars.

FIG. 10 is a block diagram of a user element in which the concepts of the present disclosure may be employed.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The present disclosure relates to a surface acoustic wave (SAW) device comprising a piezoelectric substrate and multiple electrodes that form an interdigitated transducer (IDT). To enhance transverse mode suppression and performance, the IDT is configured to have transverse shorting bars in a fast region of the IDT. Piston mode rails may also be included to further enhance transverse mode suppression and performance.

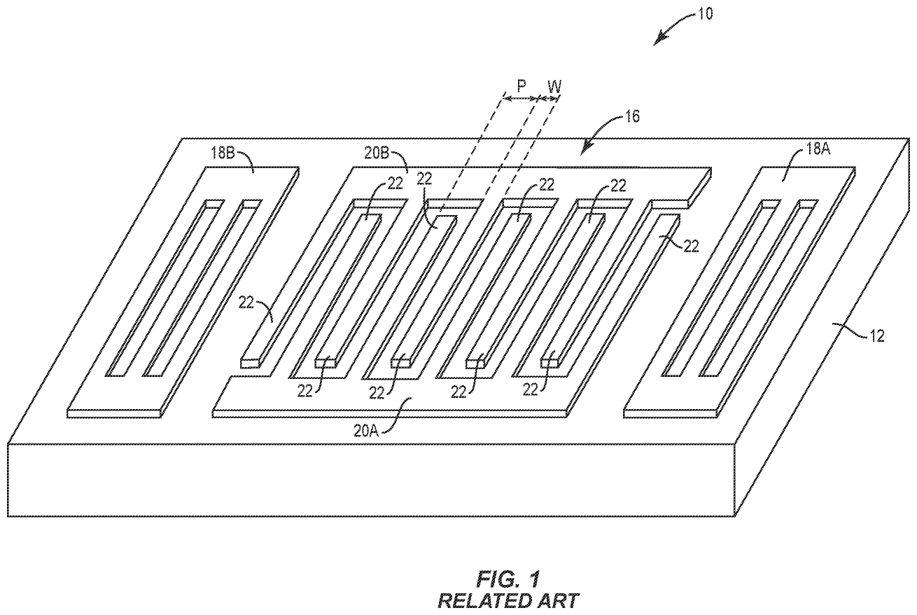

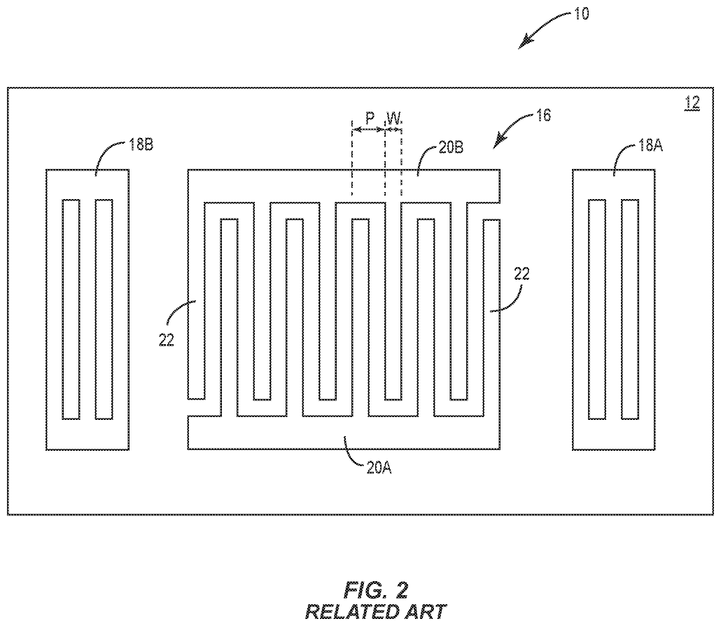

Before delving into the details, a general discussion of SAW devices is provided. FIGS. 1 and 2 are isometric and top views of a representative SAW device 10 of the related art. The SAW device 10 includes a piezoelectric substrate 12, an IDT 16 on a top surface of the piezoelectric substrate 12, a first reflector structure 18A on the top surface of the piezoelectric substrate 12 adjacent to the IDT 16, and a second reflector structure 18B on the top surface of the piezoelectric substrate 12 adjacent to the IDT 16 opposite the first reflector structure 18A. The SAW device 10 may be connected to other resonators on a die to form a more complex device like a filter. Also, it is understood that FIGS. 1 and 2 are only simplified representations of SAW devices 10. Such resonators may be more complicated comprising additional features. For example, the period between the electrodes or their polarity can vary along the transducer. In addition, only one-port resonators are represented, i.e. one transducer between two reflectors. Coupled resonator filters (CRF) can be designed by inserting several transducers between reflectors, these transducers being connected to separated electrical ports (typically input and output ports). Several of these CRFs may be connected together or connected to one-port resonators to form a device (normally a filter or a duplexer). Additionally, several geometric features may be added to the IDT to suppress unwanted spurious modes like e.g. transverse modes. Even if these devices are not specifically described, it is understood that they are within the scope of the present disclosure.

The IDT 16 includes a first electrode 20A and a second electrode 20B, each of which includes multiple electrode fingers 22 that are interleaved with one another as shown. A lateral distance between adjacent electrode fingers 22 of the first electrode 20A and the second electrode 20B defines an electrode pitch P of the IDT 16. The electrode pitch P may at least partially define a center frequency wavelength A of the SAW device 10, where the center frequency is the primary frequency of mechanical waves generated in the piezoelectric substrate 12 by the IDT 16. A finger width W of the adjacent electrode fingers 22 over the electrode pitch P may define a metallization ratio, or duty factor (DF), of the IDT 16, which will dictate certain operating characteristics of the SAW device 10, as will be appreciated by those skilled in the art.

In operation, an alternating electrical input signal provided at the first electrode 20A is transduced into a mechanical signal in the piezoelectric substrate 12, resulting in one or more acoustic waves therein. In the case of the SAW device 10, the resulting acoustic waves are predominately surface acoustic waves. As discussed above, due to the electrode pitch P, the metallization ratio of the IDT 16, the characteristics of the material of the piezoelectric substrate 12, and other factors, the magnitude and frequency of the acoustic waves transduced in the piezoelectric substrate 12 are dependent on the frequency of the alternating electrical input signal. This frequency dependence is often described in terms of changes in the impedance and/or a phase shift between the first electrode 20A and the second electrode 20B with respect to the frequency of the alternating electrical input signal.

An alternating electrical potential between the first and second electrodes 20A and 20B creates an electrical field in the piezoelectric material which generate acoustic waves. The acoustic waves travel at the surface and eventually are transferred back into an electrical signal between the first and second electrodes 20A and 20B. The first reflector structure 18A and the second reflector structure 18B reflect the acoustic waves in the piezoelectric substrate 12 back towards the IDT 16 to confine the acoustic waves longitudinally in the area surrounding the IDT 16. FIG. 2 is a top view of the SAW device 10.

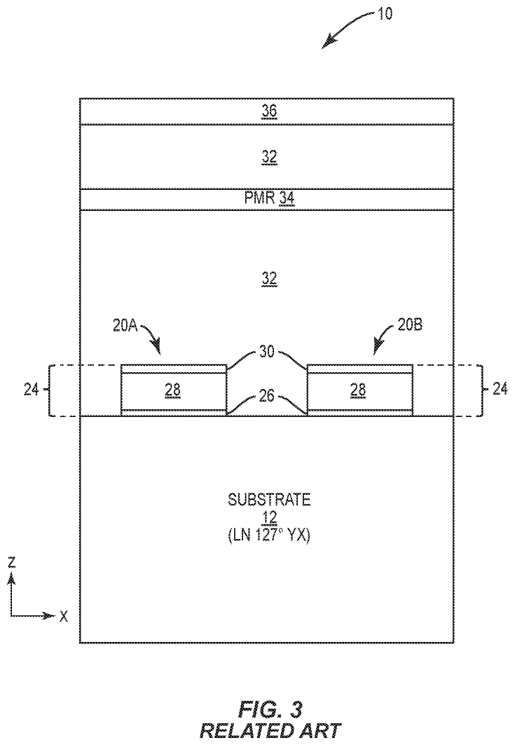

FIG. 3 is a cross-sectional view of a SAW device 10 wherein the first and second electrodes 20A and 20B are formed from a conventional electrode stack 24. The electrode stack 24 is shown with a first adhesion layer 26 on the piezoelectric substrate 12, a conducting metal layer 28 on the first adhesion layer 26, and a second adhesion layer 30 on the conducting metal layer 28. In one exemplary configuration, the first adhesion layer 26 is titanium (Ti), the conducting metal layer 28 is Cu, and the second adhesion layer 30 is Al. The first and second adhesion layers 26, 30 facilitate adhesion of adjacent layers. The piezoelectric substrate 12 can be lithium niobate, LiNbO₃ (LN) or lithium tantalate, LiTaO₃ (LT), while the piezoelectric cut angle for LN can be 127 degrees YX.

The electrode stack 24 may take on various forms and is not be limited to that described above. For example, the electrode stack 24 may take the forms of the various electrode stacks disclosed in U.S. Provisional Patent Application Ser. No. 63/435,083, filed Dec. 23, 2022, which describes electrode stacks including heavy metal temperature compensated (TC) SAW (HM-TCSAW) stack and is incorporated herein by reference in its entirety.

One or more dielectric overcoat layers 32 are provided over the first and second electrodes 20A and 20B and remaining portions of the piezoelectric substrate 12. The dielectric overcoat layer(s) 32 provides a temperature compensation layer to improve temperature stability by its positive temperature coefficient of frequency (TCF) that compensates for the negative TCF of the piezoelectric substrate 12 and other materials in the SAW device 10. The dielectric overcoat layer(s) 32 may be formed from silicon dioxide (SiO₂), doped SiO₂, or the like.

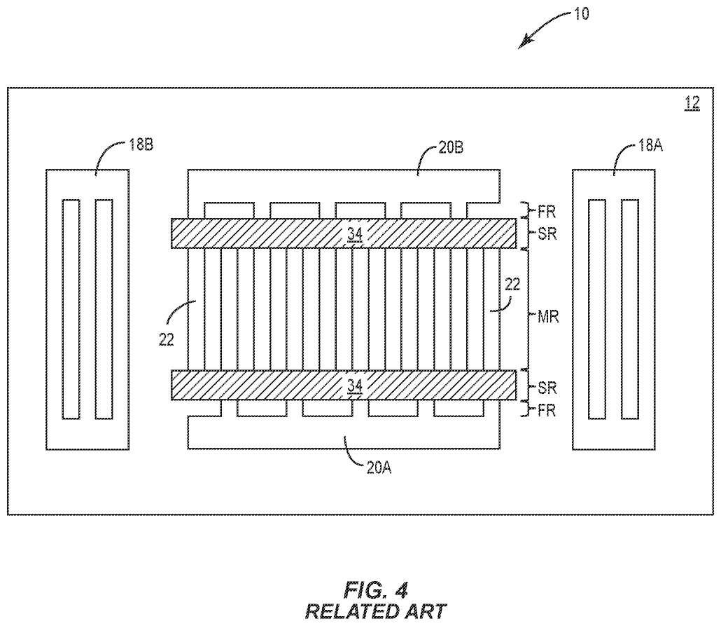

Elongated piston mode rails (PMRs) 34 may be buried in the dielectric overcoat layer 32 or provided between dielectric overcoat layers 32 in areas that extend transversely over and across the ends of the fingers 22 of the first and second electrodes 20A and 20B. The PMRs 34 are conductive and may be formed from Ti, Os, Ir, Pt, Re, W, Au, Ru, Ag, Mo, Cu, Ni, Cr, Zr and alloys of these materials. The areas over which the PMRs 34 are provided are more clearly illustrated in FIG. 4, which is a top view of the SAW device 10 in which the dielectric overcoat layer 32 is not shown. The PMRs 34 function to enable piston mode operation with better transverse mode suppression.

A slow region (SR) with relatively slower acoustic wave velocities is defined beneath the PMRs 34. A fast region (FR) with relatively faster acoustic wave velocities is provided outside of the slow regions (SRs). A main region (MR) is provided between the slow regions (SRs). The main region (MR) has the desired acoustic wave velocities, which are generally between the slower and faster acoustic wave velocities of the slow regions (SRs) and fast regions (FRs). The presence of a large enough fast region results in the guiding of the acoustic waves in the resonator and thus avoids energy leakage in transverse direction, but also results in the presence of transverse modes. The presence of the slow regions essentially results in one of the guided modes having a rectangular shape and being the only one (or almost) to be excited resulting in a Piston mode operation. As is known to those skilled in the art, other implementations are possible to obtain the same results. For example, the slow region can be realized by adding extra metal on the electrode and/or increasing the duty factor in this region. Several of these implementations may be combined to obtain the desired result. A passivation layer 36 may be formed over the dielectric overcoat layer 32 for passivation and/or trimming. The passivation layer 36 may be formed from SiO₂, Si₃N₄, or the like.

In SAW devices 10 that are configured as resonators, other than the wanted main acoustic mode, several additional unwanted spurious modes may be excited. For different SAW technologies and layer stacks the main and spurious modes can have different characteristics, such as wave polarization and localization, frequency position, and excitation strength. Moreover, depending on the desired filter parameters (i.e. frequency band and multiplexing requirements), some spurious modes may be more critical than others.

What most of the SAW technologies have in common is the existence of transverse modes, which manifest themselves in a multitude of peaks in the conductance of the resonator. Since transverse modes due to their frequency position close to the resonator's resonance are especially degrading in-band insertion loss (IL) performance and power handling capabilities, they need to be suppressed as much as possible or reasonable for filter applications.

Existing transverse mode suppression (TMS) schemes, e.g. Piston Mode Rail (PMR), Hammer Head (HH) or HH with a Shorting Bar (SB), have limits in their ability to achieve the required transverse velocity profile for good TMS. The limits are due to the specific wave velocity characteristics for the different techniques or process limits in manufacturing. Especially for a heavy metal temperature compensated (TC) SAW (HM-TCSAW) stack with thicker metal layers and higher gap aspect ratios between the metal electrodes, the existing techniques are challenging to manufacture. In case of PMRs used to create the slow region, another material would need to be used or the PMR thickness needs to be increased substantially such that good oxide coverage gets more challenging which increases reliability and quality risks. In case of HHs used to create the slow region, the DF of the HHs at the finger ends needs to be increased which makes good oxide fill between the electrodes at the finger ends in the slow region more difficult. This restricts the maximum usable DF in the main region and limits the maximum achievable size reduction of the device. Therefore, a new TMS technique is needed as an alternative to the existing ones. The new technique would help mitigate the inherent challenges of existing solutions regarding manufacturing, reliability and size while providing similar or better TMS performance.

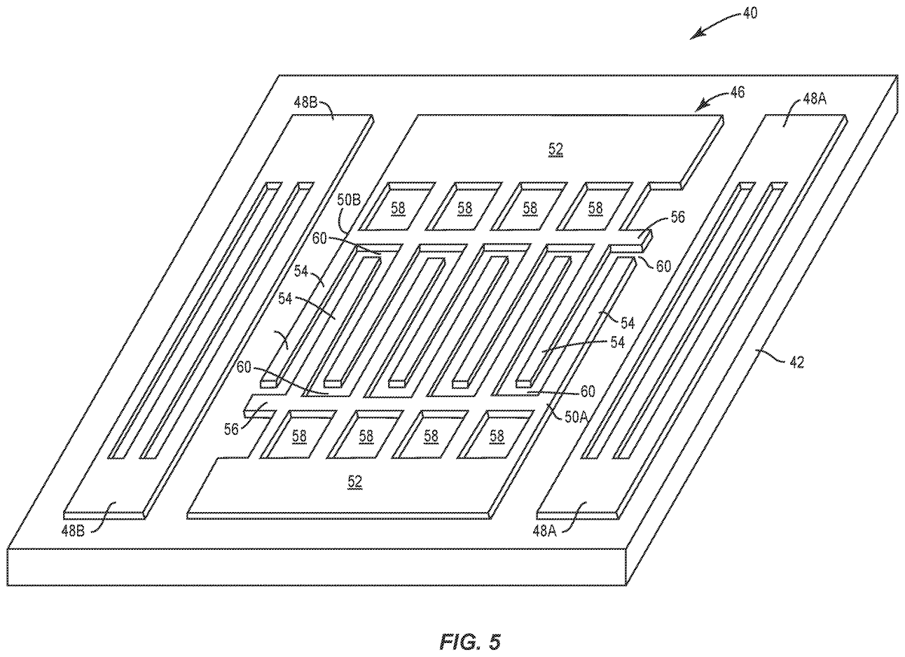

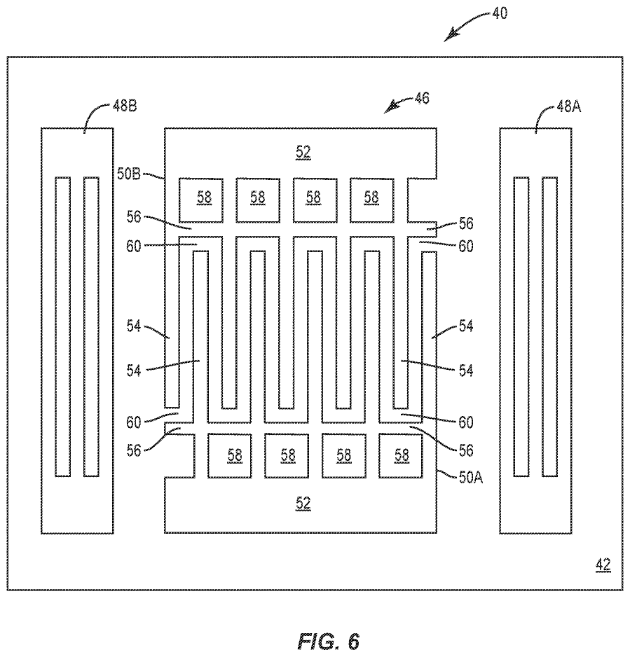

The concepts herein provide novel improvements that address the above-described issues. These improvements are described with initial reference to FIG. 5, which depicts an exemplary embodiment of a modified SAW device 40. FIGS. 5 and 6 are isometric and top views of a representative SAW device 40, according to one embodiment. The SAW device 40 includes a piezoelectric substrate 42, an IDT 46 on a top surface of the piezoelectric substrate 42, a first reflector structure 48A on the top surface of the piezoelectric substrate 42 adjacent to the IDT 46, and a second reflector structure 48B on the top surface of the piezoelectric substrate 42 adjacent to the IDT 46 opposite the first reflector structure 48A.

The IDT 46 includes a first electrode 50A and a second electrode 50B. The first electrode 50A and the second electrode 50B each including a bus bar 52, a plurality of fingers 54, and a shorting bar 56. The bus bars 52 are parallel with one another. The shorting bars 56 are parallel with each other and the bus bars 52. The shorting bar 56 of the first electrode 50A extends transversely across the fingers 54 of the first electrode 50A, wherein electrode openings 58 are defined by corresponding portions of the adjacent fingers 54, bus bar 52, and shorting bar 56 of the first electrode 50A. The shorting bar 56 of the second electrode 50B extends transversely across the fingers 54 of the second electrode 50B, wherein electrode openings 58 are defined by corresponding portions of the adjacent fingers 54, bus bar 52, and shorting bar 56 of the second electrode 50B. Further detail on the location and function of shorting bars 56 is provided below.

For the first electrode 50A, the fingers 54 are parallel with one another and extend from the bus bar 52 of the first electrode 50A, through the shorting bar 56 of the first electrode 50A, and toward the bus bar 52 of the second electrode 50B. Gaps 60 are provided between distal ends of fingers 54 of the first electrode 50A and the shorting bar 56 of the second electrode 50B. For the second electrode 50B, the fingers 54 are parallel with one another and extend from the bus bar 52 of the second electrode 50B, through the shorting bar 56 of the second electrode 50B, and toward the bus bar 52 of the first electrode 50A. Gaps 60 are provided between the distal ends of fingers 54 of the second electrode 50B and the shorting bar 56 of the first electrode 50A.

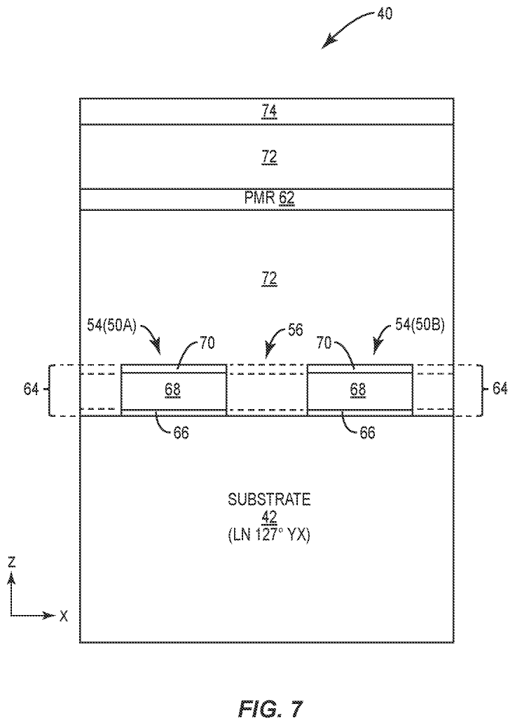

FIG. 7 is a cross-sectional view of a SAW device 40 that employs shorting bars 56 in both the first and second electrodes 50A and 50B in addition to PMRs 62 that run above and parallel with the shorting bars 56. The first electrode 50A and the second electrode 50B, which include the bus bars 52, fingers 54, and shorting bars 56, as well as the reflectors 48A, 48B of the SAW device 40 are formed from an electrode stack 64. In FIG. 7, only the fingers 54 and shorting bars 56 are illustrated.

The electrode stack 64 may be formed in various ways and with various materials and thicknesses, as those skilled in the art will appreciate. As shown, the electrode stack 64 is shown with a first adhesion layer 66 on the piezoelectric substrate 42, a conducting metal layer 68 on the first adhesion layer 66, and a second adhesion layer 70 on the conducting metal layer 68. In one exemplary configuration, the first adhesion layer 66 is titanium (Ti), the conducting metal layer 68 is copper (Cu), and the second adhesion layer 70 is aluminum (Al). However, the first and second adhesion layers 66, 70 may be formed from titanium (Ti), Chromium (Cr), Nickel (Ni), and the like or any alloy of/with them and function to provided good adhesion with adjacent layers. The adhesion layer 66 may be in direct contact with the piezoelectric substrate 12 (or other piezoelectric layer or film) with a thickness between 100-200 Å. The conducting metal layer 68 may be copper (Cu) with a thickness in the range of 1000-2000 Å (500-2500 Å). In certain embodiments, copper (Cu) may be preferable to aluminum (Al) due to its better electrical conductivity and higher mass density; however, other embodiments may employ aluminum (Al). The top adhesion layer 70 may have a thickness in the range of 100-200 Å (50-300 Å). These thicknesses and the specific layer stack are merely exemplary and non-limiting.

One or more dielectric overcoat layers 72 are provided over the first and second electrodes 50A and 50B and remaining portions of the piezoelectric substrate 42. The dielectric overcoat layer(s) 72 provides a temperature compensation layer to improve temperature stability by its positive TCF that compensates for the negative TCF of the piezoelectric substrate 42 and other materials in the SAW device 40. The dielectric overcoat layer(s) 72 may be formed from silicon dioxide (SiO₂), doped SiO₂, or the like. The piezoelectric substrate can be lithium niobate, LiNbO₃ (LN) or lithium tantalate, LiTaO₃ (LT). A passivation layer 74 may be formed over the dielectric overcoat layer 72 for passivation and/or trimming. The passivation layer 74 may be formed from SiO₂, Si₃N₄, or the like.

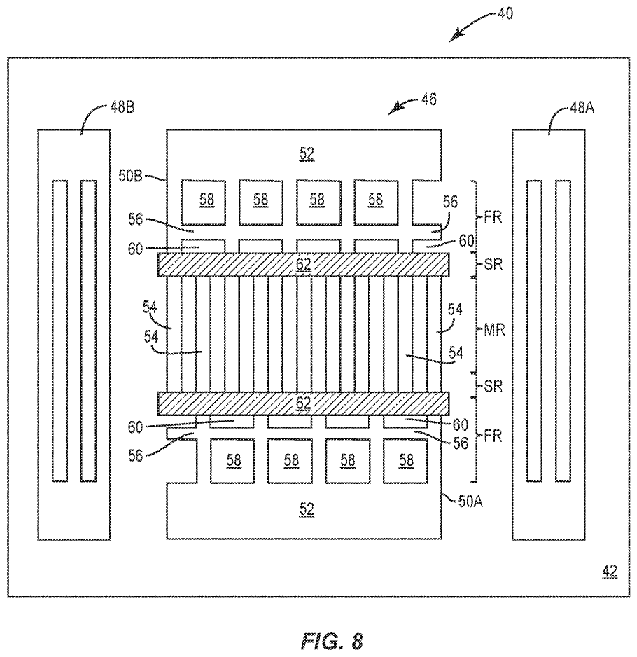

As illustrated in FIG. 7, the PMRs 62 may be buried in the dielectric overcoat layer 72 or provided between dielectric overcoat layers 72 in areas that extend transversely over and across the ends of the fingers 54 of the first and second electrodes 50A and 50B. This area over which the elongated PMRs 62 extend corresponds to the slow region (SR), as illustrated in FIG. 8. The PMRs are parallel with the shorting bars 56 and orthogonal to the fingers 54 of the first electrode 50A and the second electrode 50B.

As noted above, the slow region (SR) has relatively slower acoustic wave velocities. The fast region (FR) has relatively faster acoustic wave velocities and falls outside of the slow regions (SRs). The main region (MR) is between the slow regions (SRs). The main region (MR) has the desired acoustic wave velocities, which are generally between the slower and faster acoustic wave velocities of the slow regions (SRs) and fast regions (FRs).

With the concepts described above, a new TMS technique is described that uses PMRs 62 in combination with a shorting bar 56 in the fast region (FR). The wave velocity in the slow region comprising the PMR (vPMR) may be adjusted by the layer thickness of the PMR and its height position in the oxide. To achieve the needed transverse velocity profile for piston mode operation during TMS optimization several parameters need to be optimized, i.e. for the shorting bar the width and the distance, and for the PMR its velocity as explained above and its transverse width. The width of the fast region needs to be chosen such that good transverse acoustic waveguiding is achieved and transverse acoustic energy leakage minimized. Notably, the wave velocities beneath the shorting bars 56, while in the fast region (FR), may be lowered relative to those in the remaining portions of the fast region (FR).

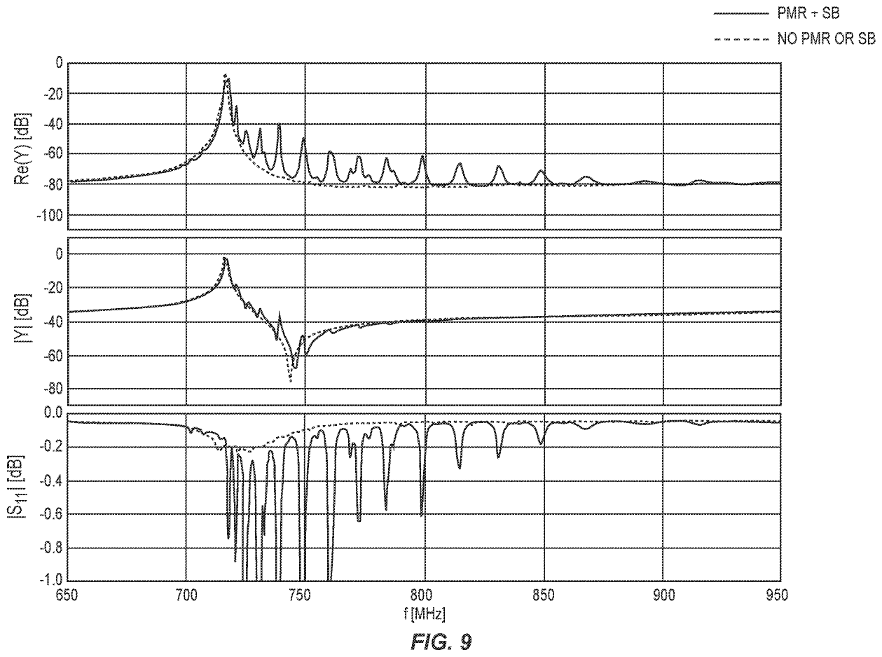

FIG. 9 shows top-down the simulated electric responses for conductance (real part of admittance Y, Re(Y)), admittance magnitude (|Y|), and return loss (|S11|) obtained by harmonic analyses using a Finite Element Method (FEM) for a SAW device with no PMRs 62 or shorting bars (SB) 56 (solid line, no PMR or SB) and the SAW device 40, which includes both PMRs 62 and shorting bars 56 (dashed line, PMR+SB). In the reference device without PMR or SB for TMS, all transverse modes are excited significantly as can be seen by multiple peaks in the conductance and dips in the return loss above resonance frequency. In contrast, the peaks/dips are very well suppressed by the concepts of the present disclosure using PMRs 62 and shorting bars 56, which results in a smooth conductance and return loss curve without peaks/dips.

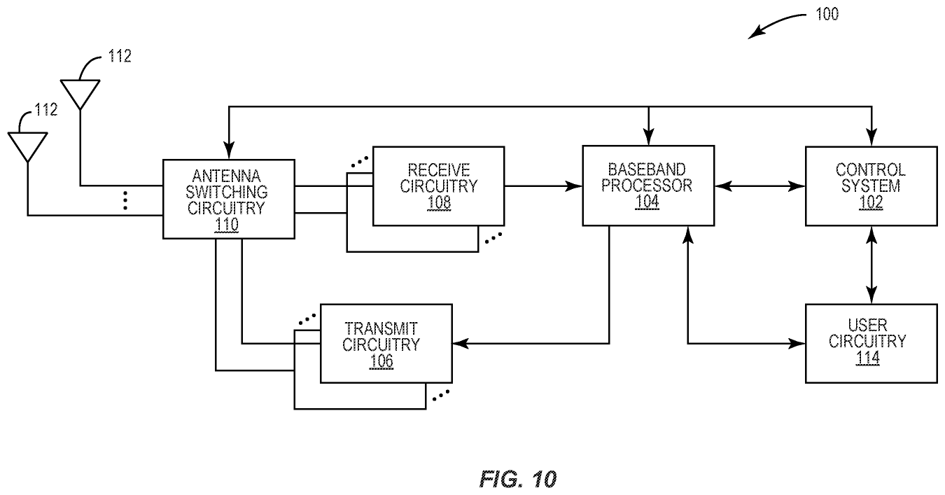

With reference to FIG. 10, the concepts described above may be implemented in various types of user elements 100, such as mobile terminals, smart watches, tablets, computers, navigation devices, access points, and like wireless communication devices that support wireless communications, such as cellular, wireless local area network (WLAN), Bluetooth, and near field communications. The user elements 100 will generally include a control system 102, a baseband processor 104, transmit circuitry 106, receive circuitry 108, antenna switching circuitry 110, multiple antennas 112, and user interface circuitry 112. In a non-limiting example, the control system 102 may be a field-programmable gate array (FPGA) or an application-specific integrated circuit (ASIC). In this regard, the control system 102 may include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter of the receive circuitry 108 cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed on greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal through the antenna switching circuitry 110 to the antennas 112. The multiple antennas 112 and the replicated transmit and receive circuitries 106, 108 may provide spatial diversity. Modulation and processing details will be understood by those skilled in the art. The SAW devices 10, 40 are particularly useful in the filters, duplexers and N-in-1 multiplexers that may be provided in the antenna switching circuitry 110, receive circuitry 108, and/or transmit circuitry 106.

Those skilled in the art will recognize improvements and modifications the preferred embodiments of the present disclosure. All such improvements and modifications are considered within the scope of the concepts disclosed herein and the claims that follow.

What is claimed is:

1. A surface acoustic wave (SAW) device, comprising:
a piezoelectric substrate;
an interdigitated transducer over the piezoelectric substrate and comprising:
a first electrode comprising a first bus bar, a first plurality of fingers extending orthogonally from the first bus bar, and a first shorting bar that is parallel with the first bus bar and extends across the first plurality of fingers; and
a second electrode comprising a second bus bar, a second plurality of fingers extending orthogonally from the second bus bar, and a second shorting bar that is parallel with the second bus bar and extends across the second plurality of fingers, wherein the second plurality of fingers are interdigitated with the first plurality of fingers; and
a first piston mode rail that is isolated from and extends over distal ends of the first plurality of fingers; and
a second piston mode rail that is isolated from and extends over distal ends of the second plurality of fingers.

2. The SAW device of claim 1 wherein:
slow regions with relatively slower acoustic wave velocities are beneath the first piston mode rail and the second piston mode rail; fast regions with relatively faster acoustic wave velocities are provided outside of the slow regions; and a main region is provided between the slow regions such that the main region has acoustic wave velocities between those of the slow regions and the fast regions;
the first shorting bar and the second shorting bar are over respective ones of the fast regions; and
the first piston mode rail and the second piston mode rail are over respective ones of the slow regions.

3. The SAW device of claim 1 wherein the first piston mode rail is parallel with the second piston mode rail, the first bus bar, and the second bus bar.

4. The SAW device of claim 1 wherein:
first openings are each defined in the first electrode by corresponding portions of the first bus bar, adjacent ones of the first plurality of fingers, and the first shorting bar; and
second openings are each defined in the second electrode by corresponding portions of the second bus bar, adjacent ones of the second plurality of fingers, and the second shorting bar.

5. The SAW device of claim 1 further comprising an overcoat layer over the first electrode, the second electrode, and portions of a top surface of the piezoelectric substrate, wherein the first piston mode rail and the second piston mode rail reside in the overcoat layer.

6. The SAW device of claim 1 wherein the piezoelectric substrate is formed from lithium niobate.

7. The SAW device of claim 1 wherein the piezoelectric substrate is formed from lithium tantalate.

8. The SAW device of claim 1 wherein the first electrode and the second electrode comprise an electrode stack, wherein the electrode stack comprises:
a first adhesion layer over the piezoelectric substrate;
a conducting layer over the first adhesion layer; and
a second adhesion layer over the conducing layer.

9. The SAW device of claim 8 further comprising an overcoat layer over the first electrode, the second electrode, and portions of a top surface of the piezoelectric substrate, wherein the first piston mode rail and the second piston mode rail reside in the overcoat layer.

10. The SAW device of claim 1 further comprising an overcoat layer over the first electrode, the second electrode, and portions of a top surface of the piezoelectric substrate, wherein the first piston mode rail and the second piston mode rail reside in the overcoat layer, wherein:
the first piston mode rail is parallel with the second piston mode rail, the first bus bar, and the second bus bar;
first openings are each defined in the first electrode by corresponding portions of the first bus bar, adjacent ones of the first plurality of fingers, and the first shorting bar; and
second openings are each defined in the second electrode by corresponding portions of the second bus bar, adjacent ones of the second plurality of fingers, and the second shorting bar.

11. The SAW device of claim 10 wherein:
slow regions with relatively slower acoustic wave velocities are beneath the first piston mode rail and the second piston mode rail; fast regions with relatively faster acoustic wave velocities are provided outside of the slow regions; and a main region is provided between the slow regions such that main region has acoustic wave velocities between those of the slow regions and the fast regions;
the first shorting bar and the second shorting bar are over respective ones of the fast regions; and
the first piston mode rail and the second piston mode rail are over respective ones of the slow regions.

12. The SAW device of claim 11 wherein:
first openings are each defined in the first electrode by corresponding portions of the first bus bar, adjacent ones of the first plurality of fingers, and the first shorting bar; and
second openings are each defined in the second electrode by corresponding portions of the second bus bar, adjacent ones of the second plurality of fingers, and the second shorting bar.

13. A method for fabricating a surface acoustic wave (SAW) device, comprising:
providing a piezoelectric substrate;
providing an interdigitated transducer over the piezoelectric substrate and comprising:
a first electrode comprising a first bus bar, a first plurality of fingers extending orthogonally from the first bus bar, and a first shorting bar that is parallel with the first bus bar and extends across the first plurality of fingers; and
a second electrode comprising a second bus bar, a second plurality of fingers extending orthogonally from the second bus bar, and a second shorting bar that is parallel with the second bus bar and extends across the second plurality of fingers, wherein the second plurality of fingers are interdigitated with the first plurality of fingers; and
providing a first piston mode rail that is isolated from and extends over distal ends of the first plurality of fingers; and
providing a second piston mode rail that is isolated from and extends over distal ends of the second plurality of fingers.

14. The method of claim 13 wherein:
first openings are each defined in the first electrode by corresponding portions of the first bus bar, adjacent ones of the first plurality of fingers, and the first shorting bar; and
second openings are each defined in the second electrode by corresponding portions of the second bus bar, adjacent ones of the second plurality of fingers, and the second shorting bar.

15. The method of claim 13 further comprising an overcoat layer over the first electrode, the second electrode, and portions of a top surface of the piezoelectric substrate, wherein the first piston mode rail and the second piston mode rail reside in the overcoat layer.

16. The method of claim 13 wherein the piezoelectric substrate is formed from lithium niobate.

17. The method of claim 13 wherein the piezoelectric substrate is formed from lithium tantalate.

18. The method of claim 13 wherein the first electrode and the second electrode comprise an electrode stack, wherein the electrode stack comprises:
a first adhesion layer over the piezoelectric substrate;
a conducting layer over the first adhesion layer; and
a second adhesion layer over the conducing layer.

19. The method of claim 18 further comprising providing an overcoat layer over the first electrode, the second electrode, and portions of a top surface of the piezoelectric substrate, wherein the first piston mode rail and the second piston mode rail reside in the overcoat layer.

20. The method of claim 13 wherein:
slow regions with relatively slower acoustic wave velocities are beneath the first piston mode rail and the second piston mode rail; fast regions with relatively faster acoustic wave velocities are provided outside of the slow regions; and a main region is provided between the slow regions such that main region has the acoustic wave velocities between those of the slow regions and the fast regions;
the first shorting bar and the second shorting bar are over respective ones of the fast regions; and
the first piston mode rail and the second piston mode rail are over respective ones of the slow regions.

21. The method of claim 20 wherein the first piston mode rail is parallel with the second piston mode rail, the first bus bar, and the second bus bar.

22. A mobile terminal comprising transmit circuitry and receive circuitry that comprises at least one surface acoustic wave (SAW) device comprising:
piezoelectric substrate;
an interdigitated transducer over the piezoelectric substrate and comprising:
a first electrode comprising a first bus bar, a first plurality of fingers extending orthogonally from the first bus bar, and a first shorting bar that is parallel with the first bus bar and extends across the first plurality of fingers; and
a second electrode comprising a second bus bar, a second plurality of fingers extending orthogonally from the second bus bar, and a second shorting bar that is parallel with the second bus bar and extends across the second plurality of fingers, wherein the second plurality of fingers are interdigitated with the first plurality of fingers; and
a first piston mode rail that is isolated from and extends over distal ends of the first plurality of fingers; and
a second piston mode rail that is isolated from and extends over distal ends of the second plurality of fingers.
